(19) United States
(12) Patent Application Publication
(10) Pub. No.: US 2026/0220340 A1
(43) Pub. Date: Jul. 30, 2026

(54) ADAPTABLE STREAMING INTERCONNECT

(71) Applicant: XILINX, INC., San Jose, CA (US)

(72) Inventors: Chandrasekhar Srinivasaiah THYAMAGONDLU, Saratoga, CA (US); Nicholas TRANK, San Jose, CA (US)

(21) Appl. No.: 19/038,461

(22) Filed: Jan. 27, 2025

(51) Int. Cl. G06F 30/32

(52) U.S. Cl. CPC G06F 30/32

(57) ABSTRACT

A system-on-chip (SoC) includes a request initiator device, a request target device, and an adaptable streaming interconnect (ASI) communicatively coupled to the request initiator device and the request target device. The ASI is configured to receive a posted request (PR) from the request initiator device, transmit the PR to the request target device, receive a posted request complete (PRC) from the request target device, and transmit the PRC to the request initiator device. The request initiator device is configured to enforce an ordering requirement of the PR based on the PRC.

### TECHNICAL FIELD

Examples of the present disclosure generally relate to integrated circuit (IC) design, and in particular to an adaptable streaming interconnect (ASI) that enables data communication among host interfaces and client devices.

### BACKGROUND

A system-on-a-chip (SoC) platform allows multiple components, such as processors, memory devices, and network interfaces, to be integrated in a single chip. Peripheral Component Interconnect express (PCIe) and the Advanced eXtensible Interface 4 (AXI4) are widely used high-speed interface protocols for connecting various components within a SoC. While attempts have been made to improve data communication among host interfaces and client devices, challenges still remain in terms of packet ordering enforcement and traffic congestion control as different protocols such as PCIe and AXI4 impose different ordering requirements. For example, under the current PCIe specification, when a posted request (PR) is sent from a request initiator (or a requester) to a request target (or a completer), the request target does not send a completion packet back to the request initiator. As a result, in order to perform ordering enforcement for the PRs, the request initiator attaches a sequence number to each posted request, and both the request initiator and target need to monitor the sequence numbers to ensure that ordering is maintained. However, as the request initiator sends posted requests to different request targets, a global ordering enforcement among all request targets can be impractical due to the high costs in data communication overhead and computing resource. In addition, the current streaming interconnect solutions lack mechanisms to effective prevent head-of-line (HOL) blocking, which can lead to inefficient resource utilization and reduced performance.

Thus, solutions for interconnecting multiple host interfaces and client devices having different interface protocols, functionalities, and ordering semantics in a SoC platform are desired.

### SUMMARY

Systems, methods, and apparatuses are described for interconnecting multiple host interfaces and client devices having different protocols, functionalities, and ordering semantics to enable high-bandwidth and low-latency data communication in a SoC.

According to one aspect, a system-on-chip (SoC) includes a request initiator device, a request target device, and an adaptable streaming interconnect (ASI) communicatively coupled to the request initiator device and the request target device, where the ASI is configured to receive a posted request (PR) from the request initiator device, transmit the PR to the request target device, receive a posted request complete (PRC) from the request target device, and transmit the PRC to the request initiator device.

According to another aspect, a method by an adaptable streaming interconnect (ASI) includes receiving a posted request (PR) from a request initiator device, transmitting the PR to a request target device, receiving a posted request complete (PRC) from the request target device, and transmitting the PRC to the request initiator device.

According to yet another aspect, an adaptable streaming interconnect, communicatively coupled to a request initiator device and a request target device, includes circuitry configured to receive a posted request (PR) from the request initiator device, transmit the PR to the request target device, receive a posted request complete (PRC) from the request target device, and transmit the PRC to the request initiator device.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a schematic diagram of a SOC environment, in accordance with an example embodiment of the present disclosure.

FIG. 2A illustrates a schematic diagram of a confidential PCIe and direct memory access module (CPM)-end point (EP) block, in accordance with an example embodiment of the present disclosure.

FIG. 2B illustrates a schematic diagram of a CPM-root port (RP) block, in accordance with an example embodiment of the present disclosure.

FIG. 3 illustrates a schematic diagram showing traffic flow through an ASI, in accordance with an example embodiment of the present disclosure.

FIG. 4 illustrates a schematic view of a capsule for transporting data and messages, in accordance with an example embodiment of the present disclosure.

FIG. 5A illustrates a schematic diagram showing PR and PRC handling by an ASI, in accordance with an example embodiment of the present disclosure.

FIG. 5B illustrates a schematic diagram showing non-posted request (NPR) and non-posted request completion (CMPL) handling by an ASI, in accordance with an example embodiment of the present disclosure.

FIG. 6 illustrates a schematic diagram of an NPR ordering scheme, in accordance with an example embodiment of the present disclosure.

FIG. 7A illustrates a flowchart of a method for managing traffic flow by an ASI, in accordance with an example embodiment of the present disclosure.

FIG. 7B illustrates a flowchart of another method for managing traffic flow by an ASI, in accordance with an example embodiment of the present disclosure.

FIG. 8A illustrates a schematic routing diagram for transmitting PRs and NPRs from PCIe bridges to user ports, in accordance with an example embodiment of the present disclosure.

FIG. 8B illustrates a schematic routing diagram for transmitting PRs and NPRs from user ports to PCIe bridges, in accordance with an example embodiment of the present disclosure.

FIG. 9 illustrates a schematic diagram showing a usage for a serializer module and a de-serializer module, in accordance with an example embodiment of the present disclosure.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive explanation of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

According to embodiments of the present disclosure, an ASI is provided to direct traffic from multiple host interfaces (e.g., PCIe and AXI interfaces) to multiple clients (e.g., processor subsystems, direct memory access (DMA) engines, PCIe-attached storages, user ports, and programmable logic (PL) kernels) in the same SoC.

A new flow type, posted request completion (PRC), is introduced. For example, in response to a posted request (PR) from a request initiator (e.g., a DMA system) being committed at a request target (e.g., a PCIe bridge), the request target generates a PRC and transmits the PRC back to the request initiator. The PRCs are either generated by the request target in order, or are re-ordered by the request target before being transmitted back to the request initiator. For example, the PRCs can be generated at the request target for a given ASI virtual channel (VC). The ASI VCs can be associated with the PCIe VCs or the AxIDs for AXI targets. As a result, the PRCs are received by the request initiator in order. As such, the request initiator can be agnostic to the ordering semantics of the request targets (e.g., PCIe and AXI semantics), and perform ordering enforcement based on the in-order PRCs. The ASI can also provide strong adaptable ordering semantics to support both PCIe and AXI ordering requirements, for example, at the request targets. Data traffic through the ASI is separated based on flow type (e.g., PR, NPR, CMPL, and PRC) to prevent any blocking between different flows. In addition, the ASI implements various credit schemes (e.g., through credited buffers) to provide credits back to the request initiators to reduce congestion and avoid HOL blocking.

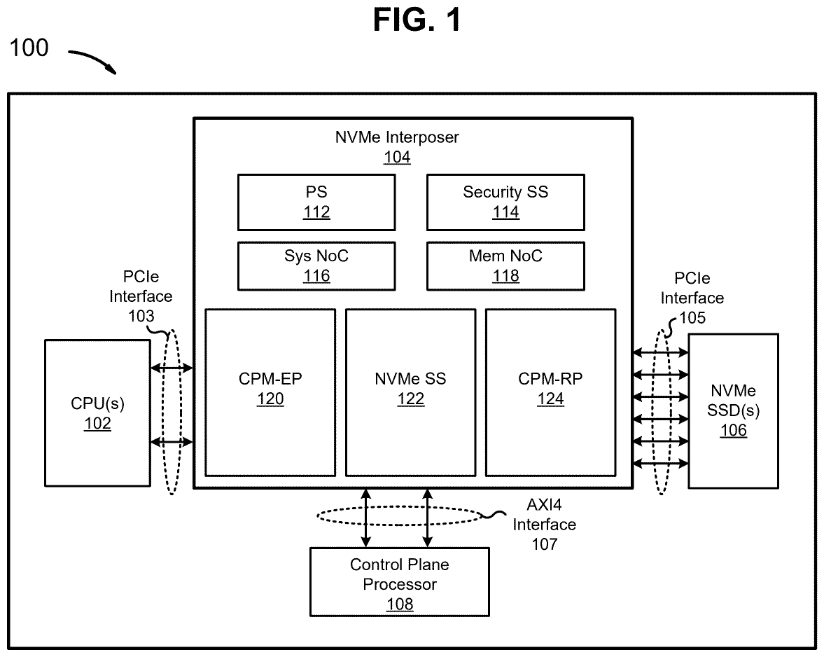

FIG. 1 illustrates a schematic diagram of a SOC environment 100, in accordance with an example embodiment of the present disclosure.

As illustrated in FIG. 1, the SOC environment 100 includes one or more host processors (e.g., CPUs) 102, a non-volatile memory express (NVMe) interposer 104, and one or more NVMe solid-state storage devices (SSDs) 106. The SOC environment 100 also includes a management subsystem 108, for example, having a baseboard management controller (BMC) and a network interface controller (NIC) that can communicate with the NVMe interposer 104 using an AXI4 interface 107.

In some embodiments, the CPUs 102 can include core processors for running operating systems and/or application processors for running applications. In a multi-host scenario, the CPUs 102 can each have an independent operating system communicating with a PCIe bus. In a bifurcation scenario, a single host (e.g., a single CPU 102) can divide a PCIe bus into multiple PCIe lanes (e.g., x16, 2×8, 4×4, and so forth) to communicate with multiple virtual machines. The CPUs 102 can execute programs having NVMe device drivers that communicate with the NVMe interposer 104. The CPUs 102 can send commands to the NVMe SSDs 106 through the NVMe interposer 104 (e.g., through the PCIe interfaces 103 and 105). These commands can specify the type of operation (e.g., read, write, and etc.), the address of the data to be accessed, and other relevant parameters. The CPUs 102 can allocate system resources, such as memory and I/O bandwidth, to ensure efficient data transfer between the CPUs 102 and the NVMe SSDs 106.

As illustrated in FIG. 1, the NVMe interposer 104 includes an NVMe processor subsystem (PS) 112, a security subsystem (SS) 114, a system network on chip (NoC) 116, and a memory NoC 118. The NVMe interposer 104 also includes a CPM-EP block 120, an NVMe subsystem 122, and a CPM-RP complex 124. It is noted that, in FIG. 1, the control and data paths in the NVMe interposer 104 are omitted for clarity.

In some embodiments, the NVMe PS 112 can include an embedded processor complex for firmware (e.g., NVMe-1 firmware) execution. In some embodiments, the NVMe PS 112 can include an on-chip memory (OCM) for high bandwidth and low latency data communication. In some embodiments, the NVMe PS 112 can configure and operate one or more SSDs via the CPM-RP complex 124 and the system NoC 116. In some embodiments, the host device drivers (e.g., the NVMe device drivers from the CPUs 102) can configure the NVMe interposer 104 via the CPM-EP block 120, where the configuration is proxied to the NVMe PS 112.

In some embodiments, the security SS 114 can include a platform IP block that provides secure boot for the firmware and other housekeeping services for the NVMe interposer 104's application-specific integrated circuit (ASIC). In some embodiments, the security SS 114 can perform cryptographic functions such as encryption and decryption to protect data, and verification to avoid silent data corruption.

In some embodiments, the system NoC 116 can include a high-speed flexible network that interconnects the components in the NVMe interposer 104. The memory NoC 118 can help optimize memory access and data transfer within the NVMe interposer 104.

In some embodiments, the CPM-EP block 120 can include a subsystem instantiated in an endpoint configuration. The CPM-EP block 120 includes a PCIe host interface that provides PCIe endpoint functionalities for one or more hosts. As a primary host interface gateway, the CPM-EP block 120 can enable the NVMe interposer 104 to participate in virtualized NVMe acceleration solutions. The CPM-EP block 120 can be connected to the NVMe PS 112 via one or more advanced extensible interface memory mapped (AXI-MM) connections (e.g., 128 Gbps AXI-MM paths). The CPM-EP block 120 can be connected to the security SS 114 via one or more asynchronous serial interface connections (e.g., 512 Gbps ASI paths).

In some embodiments, the NVMe SS 122 can include an embedded processor complex for NVMe firmware execution. The NV Me SS 122 can provide core functionalities associated with NVMe SSD virtualization features. In some embodiments, the NVMe SS 122 can provide thin provisioning such that more physical space can be presented to virtual machine (VM) guests than what exists on the backing SSDs. The NVMe SS 122 can provide redundant array of independent disks (RAID) mirroring as an option for guest volumes. The NVMe SS 122 can also provide live migration offload.

In some embodiments, the CPM-RP complex 124 can include a subsystem instantiated in a root port configuration (e.g., a PCIe Gen5 root port configuration) to enable the NVMe interposer 104 to participate in virtualized NVMe acceleration solutions. In one example, the CPM-RP complex 124 includes six PCIe root port instances (or blocks) that provide PCIe root port functionalities for six NVMe SSDs 106 via the PCIe interface 105. In one example, the CPM-RP complex 124 is the host coming up out of boot as a PCIe Gen5 root port configuration, connected to one or more NVMe physical SSDs (pSSDs).

In some embodiments, the NVMe interposer 104 is a self-contained integrated block. In some embodiments, the NVMe interposer 104 can rely on infrastructure around it for configuration, system-level management functionalities and interfaces, power, cooling, clocks, and reset sequencing.

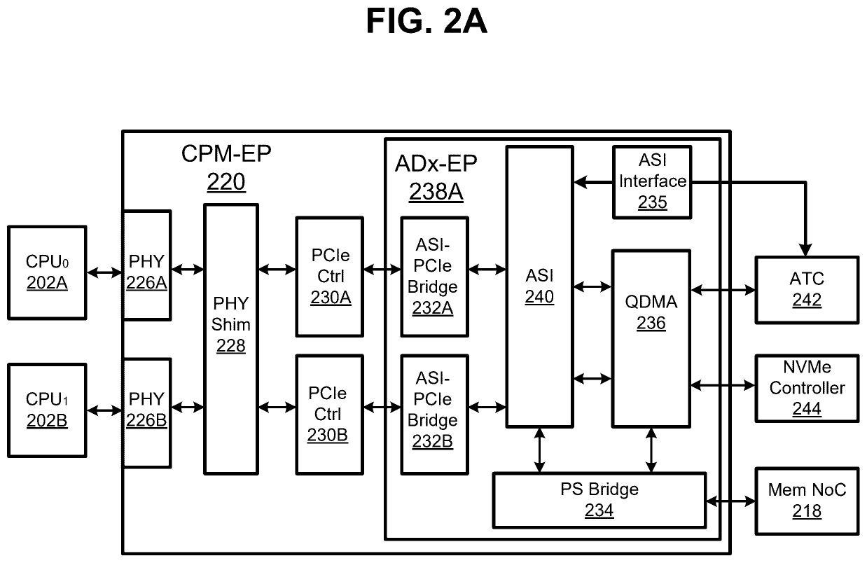

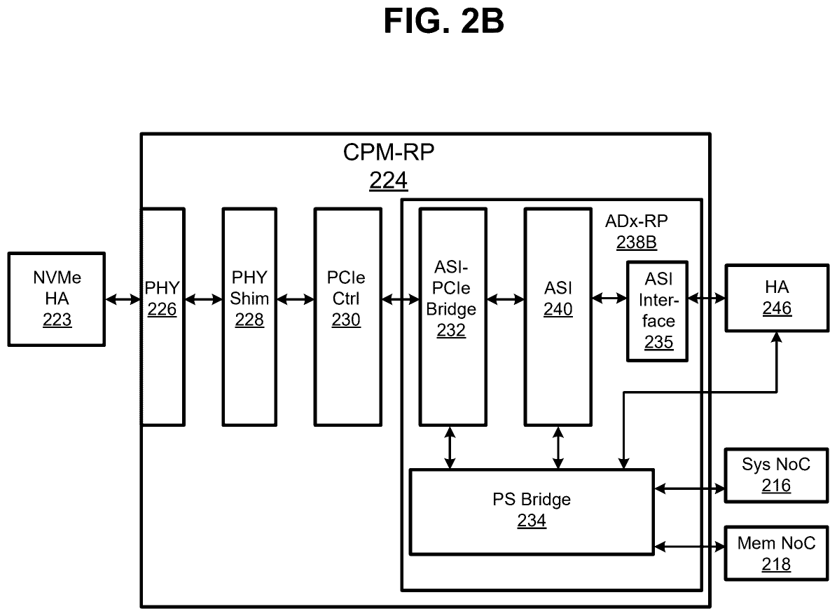

FIG. 2A illustrates a schematic diagram of a CPM-EP block 220, in accordance with an example embodiment of the present disclosure. In the present embodiment, the CPM-EP block 220 may correspond to the CPM-EP block 120 shown in FIG. 1.

As illustrated in FIG. 2A, the CPM-EP block 220 includes a physical layer (PHY) block 226A coupled to CPU₀ 202A, and a PHY block 226B coupled to a CPU₁ 202B. As an example, each of the PHY blocks 226A and 226B can include a 4-lane, 32 GT/s PCIe Gen5 PHY.

The CPM-EP block 220 also includes PCIe controllers 230A and 230B. In some embodiments, the PCIe controller 230A can be a Gen5 x16 PCIe controller, and the PCIe controller 230B can be a Gen5 x8 PCIe controller. In one example, the PCIe controller 230A can support PCIe Gen5 protocol at 32GT/s for up to x16 lane-width. In a bifurcated mode, the PCIe Gen5 x16 controller can be configured as two PCIe Gen5 x8 controllers. In one example, the PCIe controller 230B can support PCIe Gen5 protocol at 32GT/s for up to x8 lane-width.

In some embodiments, the CPM-EP block 220 can include a 16-lane, 32GT/s PCIe Gen5 PHY block which allows connectivity either in a single Gen5 x16 PCIe EP controller configuration, or in a bifurcated configuration of two Gen5 x8 PCIe EPs, where the Gen5 x16 PCIe EP controller is configured in the Gen5 x8 PCIe EP mode such that the first Gen5 x8 controller is connected to the first 8 lanes of the 32GT/s PCIe Gen5 PHY, and the second Gen5 x8 controller is connected to the second 8 lanes of the 32GT/s PCIe Gen5 PHY.

In some embodiments, the clocking and reset controls for each of the PCIe controllers 230A and 230B are forwarded to an adaptable DMA, PCIe, and host interface subsystem (ADx)-EP 238A such that it can take the appropriate actions for error-isolation firewalling AXI-MM traffic on one PCIe controller in a hung state or under reset from the other PCIe controller, which may still be operational.

As illustrated in FIG. 2A, the CPM-EP block 220 can include a PHY shim block 228 between the PHY blocks (e.g., the PHY blocks 226A and 226B) and the PCIe controllers (e.g., the PCIe controllers 230A and 230B). The PHY shim block 228 is responsible for muxing 16 lanes of Serialization/Deserialization (SERDES) to the PCIe controllers 230A and 230B.

In the CPM-EP block 220, the ADx-EP 238A is instantiated in an endpoint configuration. The ADx-EP 238A can transparently route traffic between various sources and destinations. The ADx-EP 238A includes ASI-PCIe bridges 232A and 232B, a PS bridge (e.g., an ASI-AXI bridge) 234, an ASI interface 235 (e.g., having user ports), a queue data movement accelerator (QDMA) 236 (e.g., as an NVMe bridge), and an ASI 240.

The ASI-PCIe bridges 232A and 232B can facilitate communication between the PCIe controllers 230A and 230B with the ASI 240. The PS bridge 234 can connect the AXI-MM pathways between the NVMe_PS (e.g., the NVMe PS 112 in FIG. 1) and the streaming interfaces of the PCIe controllers 230A and 230B. The PS bridge 234 is also connected to a memory NoC 218 (e.g., corresponding to the memory NoC 118 in FIG. 1).

The QDMA 236 implements the NVMe submission queue (SQ) and/or completion queue (CQ) functionalities in addition to the general purpose DMA functionalities. The QDMA 236 includes a high-performance hardware accelerator to transfer data. In some embodiments, the QDMA 236 can move data as one Gen5x16 bandwidth capable DMA engine or two virtual Gen5 x8 bandwidth capable DMA engines in the bifurcated configuration of two Gen5 x8 PCIe interfaces. In some embodiments, the QDMA 236 can directly interface with an NVMe SS (e.g., the NVMe SS 122 in FIG. 1). As illustrated in FIG. 2A, the QDMA 236 can communicate with an address translation cache (ATC) 242 and an NVMe controller 244, for example, as part of the NVMe SS.

In some embodiments, the ASI 240 can direct traffic from multiple host interfaces to multiple subsystems (or blocks) within the NVMe interposer (e.g., the NVMe interposer 104 in FIG. 1). For example, the ASI 240 can manage data flows associated with local PCIe-attached co-processors. The ASI 240 can provide PCIe-like connectivity between initiators (or sources) and targets (sinks) by means of transporting memory read requests, memory write requests, completions, and other types of transactions. The ASI 240 can also direct traffic through the ASI interface 235.

In some embodiments, the ASI 240 can manage host interfaces between a single controller mode and a bifurcated controller mode of the CPM-EP block 220 without having to replicate the DMA engines. In some embodiments, the ASI 240 is an N×M streaming fabric connecting N capsule initiators to M capsule targets. In some embodiments, the ASI 240 can scale bandwidth to 512 Gbps (PCIE Gen5x16). In addition, the ASI 240 allows the NVMe PS (e.g., the NVMe PS 112 in FIG. 1) to access the QDMA 236. The ASI 240 also allows the QDMA 236 to move data between the hosts, between any host and the OCM (e.g., connected through the memory NoC 218), and between the OCM and the NVMe controller 244. In other words, the PS bridge 234 can make the NVMe PS (connected to the system NoC and the memory NoC) to appear as a host.

FIG. 2B illustrates a schematic diagram of a CPM-RP block 224, in accordance with an example embodiment of the present disclosure. In the present embodiment, the CPM-RP block 224 may correspond to one of the root port instances in the CPM-RP complex 124 in FIG. 1. Each of the CPM-RP block 224 includes connections to the NVMe_PS via AXI-MM paths and connections to the NVMe_SS via ASI paths.

As illustrated in FIG. 2B, the CPM-RP block 224 includes a PHY block 226 coupled to an NVMe high availability (HA) block 223 of an NVMe SS (e.g., the NVMe SS 122 in FIG. 1). As an example, the PHY block 226 can include a 4-lane, 32 GT/s PCIe Gen5 PHY.

The CPM-RP block 224 also includes a PCIe controller 230. In some embodiments, the PCIe controller 230 can support PCIe Gen5 protocol at 32GT/s for up to x4 lane-width.

In some embodiments, the clocking and reset controls for the PCIe controller 230 is forwarded to an ADx-RP 238B such that it can take the appropriate actions for error-isolation firewalling AXI-MM traffic on the CPM-RP block 224 in a hung state or under reset from the other CPM-RP blocks, which may still be operational.

As illustrated in FIG. 2B, the CPM-RP block 224 also includes a PHY shim block 228 between the PHY block 226 and the PCIe controller 230. The PHY shim block 228 is responsible for muxing 4 lanes of SERDES to the PCIe controller 230.

In the CPM-RP block 224, an ADx-RP 238B is instantiated in a root port configuration. The ADx-RP 238B can transparently route traffic between various sources and destinations. The ADx-RP 238B includes an ASI-PCIe bridge 232, a PS bridge (e.g., an ASI-AXI bridge) 234, an ASI interface 235 (e.g., having user ports), and an ASI 240.

The ASI-PCIe bridge 232 can facilitate communication between the PCIe controller 230 with the ASI 240. The PS bridge 234 can connect the AXI-MM pathways between the NVMe_PS (e.g., the NVMe PS 112 in FIG. 1) and the streaming interfaces of the PCIe controller 230. The PS bridge 234 is also connected to an HA 246 (e.g., having user ports), a system NoC 216 (e.g., corresponding to the system NoC 116 in FIG. 1), and a memory NoC 218 (e.g., corresponding to the memory NoC 118 in FIG. 1).

In some embodiments, the ASI 240 can direct traffic from multiple host interfaces to multiple subsystems (or blocks) within the NVMe interposer (e.g., the NVMe interposer 104 in FIG. 1). For example, the ASI 240 can manage data flows associated with local PCIe-attached co-processors. The ASI 240 can provide PCIe-like connectivity between initiators and targets by means of transporting memory read requests, memory write requests, completions, and other types of transactions. The ASI 240 can also direct traffic through the ASI interface 235. In the CMP-RP context, the CMP-RP block 224 may have a single link to the SSD as an external PCIe endpoint. Through the ASI 240, the SSD can initiate DMA OCM operations via the memory NoC 218 or the HA 246.

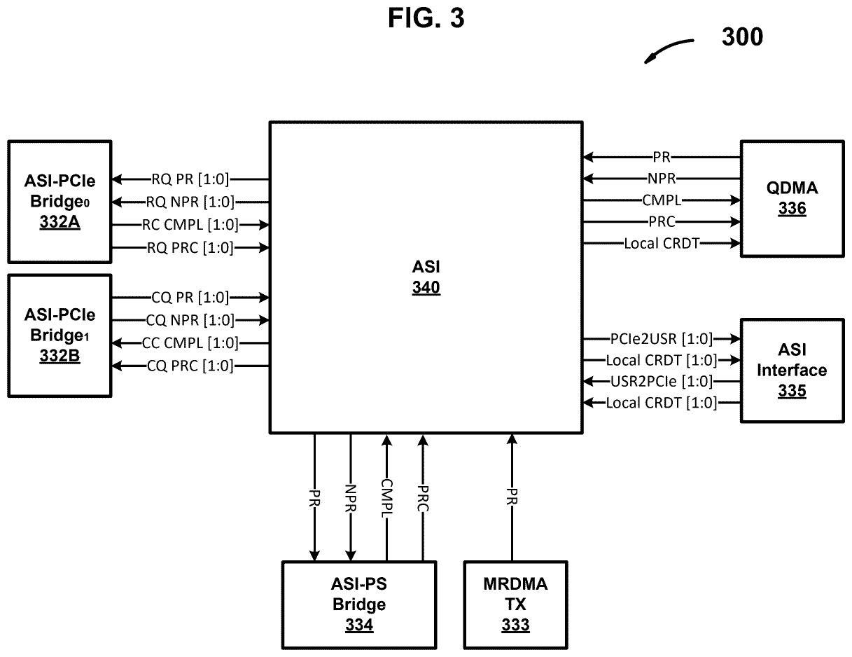

FIG. 3 illustrates a schematic diagram 300 showing traffic flow through an ASI 340, in accordance with an example embodiment of the present disclosure. The ASI 340 can transfer capsules (or packets) from initiators (or sources) to targets (or sinks). At a system level, clients of the ASI 340 (ASI clients) are request initiators (requestors) and/or request targets (completers). Both the request initiators and request targets can implement respective interfaces to the ASI 340. In some embodiments, the request initiators can be treated as capsule sources, and the request targets can be treated as capsule sinks.

As illustrated in FIG. 3, the ASI 340 provides connectivity between initiators and targets by transporting various capsules, including PRs (e.g., memory write requests), NPRs (e.g., memory read requests), PRCs (e.g., memory write completions), CMPLs (e.g., memory read completions), and other types of transactions (e.g., local credits). For example, a request initiator can transmit request capsules (e.g., PRs and NPRs) to the ASI 340, which can in turn transmit the request capsules to the request targets. In response, the request targets can transmit request complete capsules (e.g., PRCs and CMPLs) to the ASI 340, which can in turn transmit the request complete capsules to the request initiators.

In some the embodiments, the ASI 340 may provide a transport medium having PCIe-like connectivity. The ASI 340 can be regarded as a source-routed switch matrix, allowing traffic from multiple sources to be routed to multiple sinks. The sources and sinks do not need to have the same bus widths or data rates.

As illustrated in FIG. 3, the ASI 340 is coupled to ASI-PCIe bridges 332A and 332B, an ASI-PS bridge 334, an ASI interface 335 (e.g., having one or more user ports), and a QDMA 336. It should be understood that, each of the ASI-PCIe bridges 332A and 332B, the ASI-PS bridge 334, the ASI interface 335, and the QDMA 336 can be a request initiator, a request target, or both.

In one embodiment, the ASI-PCIe bridges 332A and 332B, the ASI 340, the ASI interface 335, the QDMA 336, and the ASI-PS bridge 334, may substantially correspond to the ASI-PCIe bridges 232A and 232B, the ASI 240, the ASI interface 235, the QDMA 236, and the PS bridge 234, respectively, as shown and described in FIG. 2A. In the CPM-EP context, the ASI interface 235 is connected to the ATC 242 as shown in FIG. 2A. In the CPM-RP context, the ASI interface 235 is connected to the HA 246 as shown in FIG. 2B. In the field-programmable gate array (FPGA) context, the ASI interface 235 may include user ports provided in the fabric.

As illustrated in FIG. 3, traffic through the ASI 340 is separated by flow type (e.g., PR, PRC, NPR, CMPL, and local credit) to prevent blocking between flows. In addition, ordering enforcement is performed per virtual channel and per flow type. For example, in one embodiment, capsules passing from a specific source to a specific sink are segregated into mutually non-blocking flows based on capsule type and virtual channel assignments. Capsules in the same flow may be delivered in order and are not blocked by capsules belonging to another flow.

In some embodiments, the VCs in the ASI 340 are provided end-to-end between each source-sink combination. Having more than one VC provisioned between a source and a sink for a given flow type allows multiple non-blocking flows (one per VC) to exist for that flow type between the source and the sink.

In some embodiments, the VCs in the ASI 340 support independent flows of requests, with separate buffering, flow control, ordering domains and quality of service. In some other embodiments, a VC may comprise a PR flow and an NPR flow going from a source to a sink, and a PRC flow and a CMPL flow going from the sink to the source.

In some embodiments, the ASI 340 can include one or more buffers, such as sink memory buffers, rate-limiting first-in-first-out (FIFO) buffers, and virtual FIFO (VFIFO) buffers. In an example, capsules from a capsule source (or a source client) can flow to the buffers before being transmitted to a capsule sink (or a sink client). In an example, the source clients can write to one or more buffers in the ASI 340. In another example, the sink clients can read from one or more ASI buffers in the ASI 340. In another example, one or more rate-limiting FIFO buffers are implemented in the ASI 340 (e.g., in the CQ pathway) for flow control.

The ASI 340 may have one or more throughput characteristics:
(a) A sustained throughput from any source to any accessible ASI sink buffer of the source can be provided. This may match the full bandwidth of the source.
(b) An output can be provided from any ASI sink buffer to the corresponding sink client. This can match the full bandwidth of the sink.
(c) Multiple sources can have throughput to the same sink.
(d) Scaling of bandwidth is supported.

The ASI 340 can act as a source-based router for flows from various sources. The ASI 340 can also enforce ordering rules to reduce the complexity of the bridges and avoid possible deadlock conditions.

The ASI 340 can address issues relating to the scaling up to the bandwidth requirements for the network interfaces. Based on a modular approach, the ASI 340 allows a flexible data path to be constructed incorporating multiple capsule sources, capsule sinks, and different types of data movers. The ASI interfaces can be exposed to the programmable logic (fabric) and/or the NoC.

As illustrated in FIG. 3, the QDMA 336 can transmit PRs and NPRs to the ASI-PCIe bridges 332A and 332B and the ASI-PS bridge 334 through the ASI 340. In response to receiving the PRs and NPRs from the QDMA 336, the ASI-PCIe bridges 332A and 332B and the ASI-PS bridge 334 can generate and transmit PRCs (e.g., in-order PRCs) and CMPLs to the QDMA 336 through the ASI 340, for example, per flow type and per-request channel. In some embodiments, the CMPLs may be out-of-order with respect to the NPRs, which may require the QDMA 336 to implement re-order buffers. In some embodiments, the QDMA 336 can access the OCM as well.

As illustrated in FIG. 3, the ASI-PCIe bridge 332A/332B can transmit PRs to the ASI-PS bridge 334 and/or the ASI interface 335 through the ASI 340. In response to receiving the PRs and NPRs from the ASI-PCIe bridge 332A/332B, the ASI-PS bridge 334 and/or the ASI interface 335 can generate and transmit in-order PRCs and in-order CMPLs to the ASI-PCIe bridge 332A/332B through the ASI 340, for example, per flow type and per-request channel.

As illustrated in FIG. 3, Memory-Registered Direct Memory Access (MRDMA) Transmit (TX) capsules can be transmitted to the ASI 340 using a separate PR interface, a MRDMA TX 333. In some embodiments, MRDMA Receive (RX) capsules can be combined with PCIe CQ capsules (e.g., CQ PRs and/or CQ NPRs) into the ASI 340.

In some embodiments, the QDMA 336 can use a 1024-bit data width for PRs and CMPLs. In some embodiments, the ASI-PCIe bridge 332A/332B, and the ASI-PS bridge 334 can each use a 512-bit data width for PRs and CMPLs. In some embodiments, the ASI-PCIe bridge 332A/332B and the ASI-PS bridge 334 can each use a 256-bit data width for NPRs. In some embodiments, NPRs with data are supported by the ASI 340 for the ASI-PCIe bridges 332A and 332B, the ASI-PS bridge 334, and the ASI interface 335.

In some embodiments, the ASI interface 335 can includes two user ports (e.g., user port LO and user port UP) that use a packed interface that serializes capsule types onto a single interface.

In some embodiments, ASI-PS bridge slave requests can be routed through the QDMA 336 for PR and NPR generations.

In some embodiments, unpacked interfaces are used to carry capsule information (e.g., as sideband to data) to allow for higher performance. The data bandwidth of an unpacked interface can range from 256-bit, 512-bit, 1024-bit, or higher. Cyclic redundancy check (CRC) can be included as a sideband field rather than in-band. In some embodiments, the capsule header is valid on all cycles, while the CRC is valid only on the end of packet (EOP) cycle. The ASI-PCIe bridges 332A and 332B, the QDMA 336, the ASI-PS bridge 334, the MRDMA TX 333, and the ASI interface 335 can utilize unpacked interfaces to saturate the PCIe bandwidth.

In some embodiments, packed interfaces are used to reduce the number of wires. The data bandwidth of a packed interface can range from 256-bit, 512-bit, or higher. In some embodiments, the packed interfaces can be used by user ports to reduce fabric pin count, as well as NPR interfaces that support deferred memory writes (e.g., PCIe CQ). In one embodiment, the ASI 340 is responsible for unpacking and multiplexing these interfaces. Packed interfaces can be used to carry a single flow-type or multiple flow types, where the flow type can be included as part of the header information. The CRC can be appended as final 4 dwords of data, which may require padding between the payload and the CRC. If the payload is aligned to the data width, then the CRC may consume an additional beat of payload.

In some embodiments, the packed interface definition can be simpler than the unpacked interface definition, as a single data field can carry the header, payload, and CRC information.

As illustrated in FIG. 3, credits can be used to provide a flow control mechanism where one or more buffers in the ASI 340 can provide local credits to the request initiators and/or request targets to prevent HOL blocking per channel and per flow type. In some embodiments, some source or sink clients may only support a single VC of a particular flow type, thus may not use local credits.

In some embodiments, credit interfaces are used to return credits to the request initiator to prevent HOL blocking among request targets (e.g., used by the QDMA 336) or to prevent HOL blocking among flow types on a serialized interface (e.g., used by the ASI interface 335). The ASI 340 and various client devices are expected to abide by the crediting scheme.

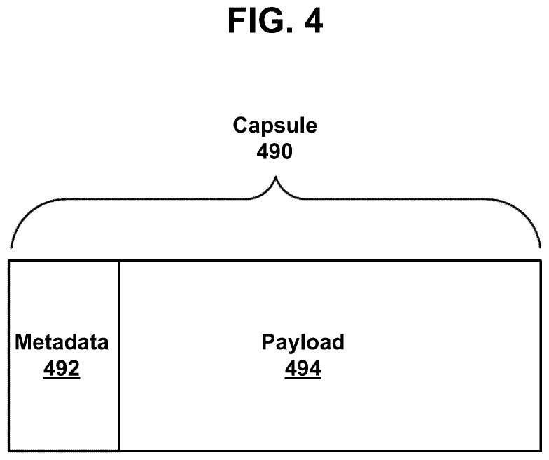

FIG. 4 illustrates a schematic view of a capsule 490 for transporting data and messages, in accordance with an example embodiment of the present disclosure. As schematically shown in FIG. 4, the capsule 490 includes metadata 492. The metadata 492 may be provided at the beginning of the capsule 490. The metadata 492 may be followed by a payload 494.

The content of the metadata 492 may depend on whether the capsule is a control capsule or a network packet capsule. The metadata 492 may include a capsule header which may be common to the control capsule and the network packet capsule. The capsule header may include information indicating if the capsule is a control capsule or a network packet capsule. The capsule header may include route information which controls the routing of the packet through the streaming subsystem. The capsule header may include virtual channel information indicating the virtual channel to be used by the capsule. The capsule header may include length information indicating the capsule length. In some embodiments, the capsule header can be included in the side-band information, for example, in the NVMe interposer. In some embodiments, the capsule header can be included in the in-band information (e.g., as an in-band header) to save fabric pins in the FPGA.

The network packet capsule can have a network capsule header following the capsule header as part of the metadata 492. This may indicate the layout of the capsule metadata and if the capsule payload includes or not an Ethernet FCS (frame check sequence). The network packet capsule can have the capsule metadata followed by, for example, an Ethernet frame in the payload.

The metadata for the control capsule may indicate the control capsule type. The capsules can have metadata to indicate offsets, which can indicate the beginning of the data.

Some embodiments may be arranged to allow data to be passed through the ASI at relatively high rates between a plurality of different capsule sources and capsule sinks.

Some embodiments may provide a composable DMA (cDMA) architecture to facilitate the passing of the data. The composability may allow different elements of a DMA system to be added, and/or the capabilities of endpoints altered without having to re-design the system. In other words, different DMA schemes with different requirements can be accommodated by the same cDMA architecture.

The architecture is scalable and/or adaptable to different requirements. The architecture is configured to support the movement of data between the host and other parts of the NVMe interposer (e.g., the NVMe interposer 104 in FIG. 1). In some embodiments, the architecture can support relatively high data rates.

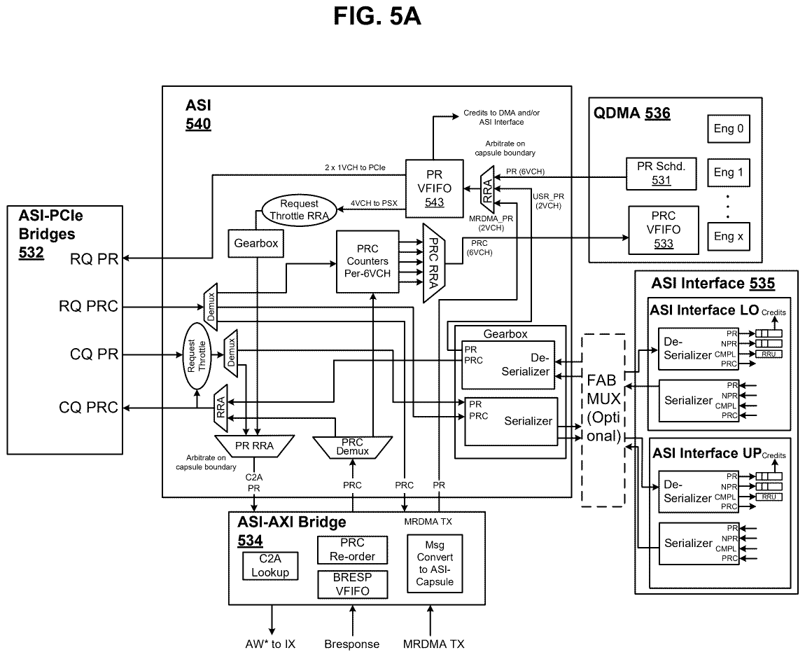

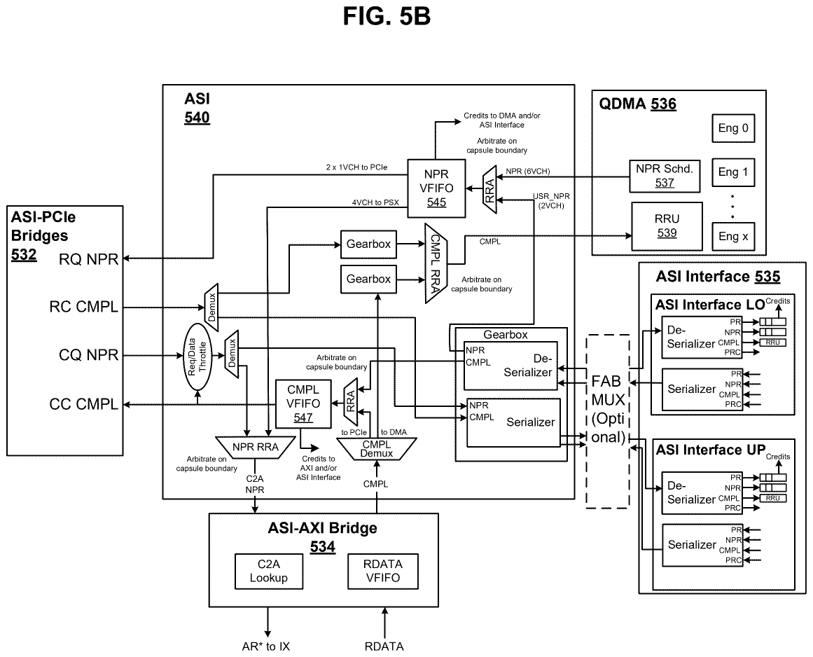

FIGS. 5A and 5B illustrate schematic diagrams showing PR and PRC handling and NPR and CMPL handling, respectively, by an ASI 540, in accordance with example embodiments of the present disclosure. In the embodiments shown in FIGS. 5A and 5B, the ASI 540 can be connected to ASI-PCIe bridges 532, an ASI-AXI bridge 534, an ASI interface 535, and a QDMA 536.

In the embodiments shown in FIGS. 5A and 5B, capsules (e.g., PRs, NPRs, PRCs, and CMPLs) are used to transport data through the ASI 540. The ASI 540 can use a common header definition for all capsules and capsule types. For example, an ASI header is used to route the capsule to the correct destination, as well as determine the payload length (if applicable).

As illustrated in FIG. 5A, each of the ASI-AXI bridge 534, the ASI interface 535, and the QDMA 536 (e.g., as a PR initiator) can transmit PRs to the ASI-PCIe bridges 532 (e.g., as a PR target) through the ASI 540. In response to receiving the PRs (e.g., after data in the PR is committed to an ordering domain of the PR target), the ASI-PCIe bridges 532 can transmit PRCs back to the ASI-AXI bridge 534, the ASI interface 535, and the QDMA 536 through the ASI 540.

As illustrated in FIG. 5A, the ASI includes a PR VFIFO buffer 543 that receives PRs from the ASI-AXI bridge 534, the ASI interface 535, and the QDMA 536 (as PR sources), and provides the PRs to the ASI-PCIe bridges 532 (e.g., as a PR target). The PR VFIFO buffer 543 can maintain a VC for each of the PR sources. In one example, the number of PR channels (e.g., VCHs) that the QDMA 536 uses in the ASI 540 can be 6, including 4 channels towards an ASI-AXI bridge 534 and 2 channels towards an ASI-PCIe bridges 532. The PR VFIFO buffer 543 can provide buffering to avoid HOL blocking and to help match the bandwidth of the ASI-PCIe bridges 532. Also, the PR sources (e.g., a PR scheduler 531 in the QDMA 536 in FIG. 5A) are responsible for limiting the outstanding PRs to prevent HOL blocking, for example, by setting a limit for the number of PRs allowed outstanding without completion (PRCs) and by receiving credits from the PR VFIFO buffer 543. In some embodiments, the PR VFIFO buffer 543 has a buffer depth that is sufficient to absorb the latency of PR capsule generation to PRC. In some embodiments, the PR VFIFO buffer 543 can provide the flexibility of allocating the space differently based on the number of PCIe links configured.

As illustrated in FIG. 5A, arbitrators, throttle counters, and/or gearboxes are implemented in the ASI 540 in the PR paths where the ASI-PCIe bridges 532 are the PR target. In some embodiments, in the ASI 540, round-robin arbitrators (RRAs) can perform arbitration at the granularity of the ASI capsules. In some embodiments, switching can be performed on various transaction layer packet (TLP) boundaries. In some embodiments, gearboxes are implemented to convert data widths (e.g., to match the width of the initiators and targets). In some embodiments, throttle counters are implemented using PRC to limit outstanding PRs and avoid PRs blocking NPRs in the ASI-PCIe bridges 532.

As illustrated in FIG. 5A, the ASI-PCIe bridges 532 (e.g., as a PR initiator) can also transmit PRs to the ASI-AXI bridge 534 and/or the ASI interface 535 (e.g., as PR targets) through the ASI 540. In some embodiments, the ASI-PCIe bridges 532 can transmit PRs from a PCIe host to the ASI-AXI bridge 534 and/or the ASI interface 535 through the ASI 540. In response to receiving the PRs (e.g., after data in the PR is committed to the PCIe ordering domain), the ASI-AXI bridge 534 and/or the ASI interface 535 can transmit PRCs back to the ASI-PCIe bridges 532 through the ASI 540.

As illustrated in FIG. 5A, when the ASI-PCIe bridges 532 function as a PR initiator/source, the ASI-AXI bridge 534 and/or the ASI interface 535 provide sufficient buffering for the PRs. In addition, arbitrators (e.g., RRAs), throttle counters, and/or gearboxes are implemented in the ASI 540 in the PR paths where the ASI-PCIe bridges 532 are the PR initiator. In some embodiments, in the ASI 540, the data path bandwidth can match that of the fastest initiator. In some embodiments, gearboxes are implemented to match each initiator and target bandwidth. The ASI 540 also provides configurable throttle for each initiator to avoid HOL blocking among the sources due to backpressure from the target.

In some embodiments, the QDMA 536 may require that the PRCs from the ASI 540 arrive in the same order as PRs sent per-source and per-virtual channel. For PRCs coming from the ASI-PCIe bridges 532, the order may be already guaranteed. However, for PRs to the ASI-AXI bridge 534 that may be using multiple AxIDs, the PRCs generated by the Bresponses may be out-of-order. This may also apply to the PCIe CQ PRs to the ASI-AXI bridge 534, which uses PRCs for read/write ordering. As a result, the ASI 540 may require that clients (e.g., the ASI-AXI bridge 534) to re-order all of the PRCs before returning to the ASI 540. For example, the ASI-AXI bridge 534 can implement a re-ordering scheme to ensure all the PRCs to be transmitted to the ASI 540 are in order.

In addition, the ASI 540 guarantees that all PRs received within a specific channel (e.g., a VC) will be sent to the destination in that same order. Since the PRCs are generated by the request target upon PR commit, the PRCs received by the request initiator (or the data source) are also in order. Thus, upon receiving the PRCs, the request initiator can perform ordering enforcement solely based on the in-order PRCs, rather than relying on other ordering mechanisms, such as using sequence numbers.

As illustrated in FIG. 5A, a PR crediting scheme is implemented using the PR VFIFO buffer 543 in the ASI 540 to avoid HOL blocking. In the present embodiment, the ASI 540 is responsible for routing PRs from the QDMA 536, the ASI-AXI bridge 534, and/or the ASI interface 535 to their destinations. In order to prevent HOL blocking, the PR VFIFO buffer 543 returns PR credits back to the PR scheduler 531 and/or the ASI interface 535 once the PRs in the corresponding VCs exit the PR VFIFO buffer 543. This PR crediting scheme allows for the PR scheduler 531 (and/or the ASI interface 535) to intelligently schedule PRs (e.g., write requests) and maintain performance across all channels. The PR VFIFO crediting scheme may use static crediting per-channel, with the total VFIFO storage divided among all of the channels (e.g., per-channel) and possible PR initiators (e.g., per-initiator).

In some embodiments, PR crediting may not be required for the CQ PRs to the ASI-AXI pathway when multi-channel is not supported. For example, the ASI-PCIe bridges 532 may only maintain one ordering domain for the CQ PRs, thus when the destination has a sufficient buffer, no additional buffer space is required in the ASI 540, and no PR crediting is required. The ASI-PCIe bridges 532 limit the total outstanding PRs without completion (PRCs).

As illustrated in FIG. 5B, each of the ASI interface 535 and the QDMA 536 (e.g., as an NPR initiator) can transmit NPRs to the ASI-PCIe bridges 532 (e.g., as an NPR target) through the ASI 540. In response to receiving the NPRs, the ASI-PCIe bridges 532 can transmit CMPLs back to the ASI interface 535 and the QDMA 536 through the ASI 540.

As illustrated in FIG. 5B, the ASI 540 includes an NPR VFIFO buffer 545 that receives NPRs from one or more of the ASI interface 535 and an NPR scheduler 537 of the QDMA 536 (as NPR sources), and provides the NPRs to the ASI-PCIe bridges 532 (e.g., as an NPR target). The NPR VFIFO buffer 545 can maintain a VC for each of the NPR sources. In one example, the number of NPR channels (e.g., VCHs) that the QDMA 536 uses in the ASI 540 can be 6, including 4 channels towards the ASI-AXI bridge 534 and 2 channels towards the ASI-PCIe bridges 532. The NPR VFIFO buffer 545 can provide buffering to avoid HOL blocking. Also, the NPR sources (e.g., the NPR scheduler 537 in the QDMA 536 in FIG. 5B) are responsible for limiting the outstanding NPRs to prevent HOL blocking, for example, by setting a limit for the number of NPRs allowed outstanding without completion (CMPLs) and by receiving credits from the NPR VFIFO buffer 545. In some embodiments, the VCs in the NPR VFIFO buffer 545 can share the space between the ASI interface 535 and the QDMA 536. In some embodiments, the space allocation can be done at the NPR sources. In some embodiments, as an NPR target, the ASI-PCIe bridges 532 provide sufficient NPR buffering for the NPR sources.

As illustrated in FIG. 5B, arbitrators (e.g., RRAs), throttle counters, and/or gearboxes are implemented in the ASI 540 in the NPR paths where the ASI-PCIe bridges 532 are an NPR target and in the CMPL paths where the ASI-PCIe bridges 532 are a CMPL source. In some embodiments, in the ASI 540, the CMPL data path bandwidth can match that of the fastest initiator. In some embodiments, gearboxes are implemented in the CMPL paths to match the bandwidth of each initiator and target. The ASI 540 also provides configurable request and data throttle for each initiator to avoid HOL blocking. Also, rate matching buffers can be implemented for associated CMPLs from the target to avoid HOL blocking due to slow drain by the ASI-PCIe bridges 532.

As illustrated in FIG. 5B, the ASI-PCIe bridges 532 (e.g., as an NPR initiator) can transmit NPRs to the ASI-AXI bridge 534 and/or the ASI interface 535 (e.g., as NPR targets) through the ASI 540. In response to receiving the NPRs, the ASI-AXI bridge 534 and the ASI interface 535 can transmit CMPLs back to the ASI-PCIe bridges 532 through the ASI 540.

As illustrated in FIG. 5B, arbitrators, throttle counters, and/or gearboxes are also implemented in the ASI 540 in the NPR paths where the ASI-PCIe bridges 532 are the NPR initiator. In some embodiments, in the ASI 540, round-robin arbitrators (RRAs) can perform arbitration at the granularity of the ASI capsules. In some embodiments, gearboxes are implemented to convert data widths (e.g., to match the width of the initiators and targets). In some embodiments, throttle counters are implemented using CMPLs to limit outstanding NPRs.

As illustrated in FIG. 5B, the QDMA 536 transmits NPRs to the ASI-PCIe bridges 532 through the ASI 540. The ASI-PCIe bridges 532 transmit the NPRs to the PCIe host, which in response may provide the associated CMPLs back to the ASI-PCIe bridges 532 in CMPL flows. The ASI-PCIe bridges 532 then transmit the CMPLs back to the QDMA 536 through the ASI 540. For example, the QDMA 536 includes the NPR scheduler 537 (e.g., a read scheduler) for scheduling NPRs and a response reassembly unit (RRU) 539 for receiving CMPLs.

As illustrated in FIG. 5B, the ASI interface 535 (e.g., the User Port-LO) can transmit NPRs to the ASI-PCIe bridges 532 and/or the ASI-AXI bridge 534 through the ASI 540. After the NPRs are received, the ASI-PCIe bridges 532 can generate and transmit CMPLs to the ASI interface 535 through the ASI 540. In some embodiments, the ASI-AXI bridge 534 can also generate and transmit CMPLs to the ASI interface 535 through the ASI 540.

In the embodiment shown in FIG. 5B, the ASI 540 may not provide any re-ordering capabilities for CMPLs (e.g., read completions). The ASI 540 uses a CMPL VFIFO buffer 547 to buffer the CMPLs towards the ASI-PCIe bridges 532. The QDMA 536 may be required to maintain their own re-order logic. NPR ordering is guaranteed within a request channel, but may be not guaranteed across different request channels or destinations. Clients (e.g., request targets) can implement their own ordering schemes using completion capsules if any specific ordering requirements are needed, for example, to ensure the CMPLs transmitted to the ASI 540 are in order.

As a result, a global ordering enforcement can be achieved by the implementations of in-order PRCs generated by the request targets and received by the request initiators, where the in-order PRCs are transmitted back to the request initiators per flow type and per channel. The request initiators can enforce their ordering requirements of the PRs based on the PRCs received in-order. It is noted that the ordering enforcement based on PRCs can be performed at an address translation cache (ATC). In one embodiment, with reference to FIG. 5A, the PRs from the ASI interface 535 has dependency in the PRs from the QDMA 536. For example, as an ordering rule, the PRs from the ASI interface 535 should not bypass the prior PRs from the QDMA 536. As a result, the PRCs are generated in-order. Thus, the ordering enforcement based on PRCs can be performed at the ATC (e.g., coupled to the ASI interface 535). Also, the DMA engines can be agnostic to the presence of the PCIe and AXI semantics.

As illustrated in FIG. 5B, an NPR crediting scheme is implemented using the NPR VFIFO buffer 545 in the ASI 540 to avoid HOL blocking. In the present embodiment, the ASI 540 is responsible for routing NPRs from the QDMA 536 and/or the ASI interface 535 to their destinations. In order to prevent HOL blocking, the NPR VFIFO buffer 545 returns NPR credits back to the NPR scheduler 537 and/or the ASI interface 535 once the NPRs in the corresponding VCs exit the NPR VFIFO buffer 545. This NPR crediting scheme allows for the NPR scheduler 537 (and/or the ASI interface 535) to intelligently schedule NPRs (e.g., read requests) and maintain performance across all channels. The NPR VFIFO crediting scheme may use static crediting per-channel, with the total VFIFO storage divided among all of the channels (e.g., per-channel) and possible NPR initiators (e.g., per-initiator).

In some embodiments, NPR crediting may not be required for the CQ NPRs to the ASI-AXI pathway when multi-channel is not supported. For example, the ASI-PCIe bridges 532 may only maintain one ordering domain for the CQ NPRs, thus when the destination has a sufficient buffer, no additional buffer space is required in the ASI 540, and no NPR crediting is required. The ASI-PCIe bridges 532 limit the total outstanding NPRs without completion (CMPLs). In some embodiments, NPR crediting may not be required for the CMPL VFIFO because it is required that the DMA/PCIe bridges always need to be able to drain completions when scheduling NPRs.

As illustrated in FIG. 5B, a CMPL crediting scheme is implemented using the CMPL VFIFO buffer 547 in the ASI 540. The CMPL VFIFO buffer 547 functions as a rate matching buffer as the CC interface of the ASI-PCIe bridges 532 could be much slower than the ASI interface 535. The CMPL VFIFO buffer 547 can also avoid HOL blocking. In the present embodiment, the ASI 540 is responsible for routing CMPLs from the ASI-AXI bridge 534 and/or the ASI interface 535 to their destinations. In order to prevent HOL blocking, the CMPL VFIFO buffer 547 returns CMPL credits back to the ASI-AXI bridge 534 and/or the ASI interface 535 once the CMPLs in the corresponding VCs exit from the CMPL VFIFO buffer 547. The CMPL crediting scheme may use static crediting per-channel, with the total VFIFO storage divided among all of the channels (e.g., per-channel) and possible CMPL initiators (e.g., per-initiator).

In the embodiments shown in FIGS. 5A and 5B, in order to prevent HOL blocking between different flow types, the ASI 540 provides a user port-to-ASI crediting mechanism for the ASI interface 535 to receive PRs, NPRs, and/or CMPLs and return credits to the ASI 540. The capsule types supported for crediting from the ASI interface 535 towards the ASI 540 include:
(a) user port PR towards PCIe RQ;
(b) user port NPR towards PCIe RQ; and
(c) user port CMPL towards PCIe CC.

Each of these flows are routed into separate VFIFOs, and so a static crediting scheme is implemented.

In the embodiments shown in FIGS. 5A and 5B, the following flow types can be multiplexed together onto the packed interfaces towards the ASI interface 535, and provide an ASI-to-user port crediting scheme to prevent any downstream (on the PL side) HOL blocking:
(a) PCIe CQ PR towards user port;
(b) PCIe CQ NPR towards user port; and
(c) PCIe RC CMPL towards user port.

In some embodiments, the ASI 540 may not interface directly with any PL FIFOs or buffer space, a crediting scheme is implemented to flow control the capsules going out of the ASI 540 towards the ASI interface 535.

In the ASI 540 shown in FIGS. 5A and 5B, the flows are independent, and capsules are delivered in order from a source to a destination for a given VC. For example, the ASI-PCIe bridges 532, as a source, implement the PCIe ordering rules/requirements. The ASI-AXI bridge 534, as a source, implements the AXI4 ordering rules/requirements. The QDMA 536 implements AXI4 style proprietary ordering rules/requirements. The ASI-PCIe bridges 532, as a source, can implement PCIe strong producer/consumer ordering model according to the existing PCIe specification.

According to embodiments of the present disclosure, PR flows can be used for PCIe memory write (PCIe MWr) messages, PCIe messages, MSI-X messages and so on. The ASI 540 delivers PR capsules in-order for a given PCIe VC. For example, the ADx-EP 238A in FIG. 2A and ADx-RP 238B in FIG. 2B can support a single PCIe VC per PR flow.

As a PR source, the ASI-PCIe bridges 532 can form PR capsules, identify the destination and VC for each PR capsule, and deliver the whole capsule without any bubble in the capsule. In some embodiments, for robustness, the ASI 540 can handle bubbles. In some embodiments, the ASI-PCIe bridges 532, as a source, can implement a single VC for the PR capsules. The ASI 540 returns the PRCs to the ASI-PCIe bridges 532 in-order.

In some embodiments, the ASI-PCIe bridges 532, as a PR source, can implement a PR sequence counter (pr_seq) and a PRC sequence counter (prc_seq), where the PR sequence counter is incremented for every PR capsule sent, and the PRC sequence counter is incremented for last PRC completion received. When pr_seq==prc_seq, the PR flow is in an idle condition. When pr_seq-1=prc_seq, the PR flow is in a full condition. To protect sequence number from wrapping, the ASI-PCIe bridges 532 can stop sending PR capsules when the PR flow is full. In one example, the ASI-PCIe bridges 532 can allow a maximum of 255 outstanding PRs. In another example, the full condition can be avoided by using a sufficiently large counter.

As a PR source, the ASI-PCIe bridges 532 can deliver PRs (e.g., PR TLPs) to multiple destinations. To be PCIe compliant, when the RO=0, the ASI-PCIe bridges 532 can perform destination switching if PR flow is idle. When RO=1, the ASI-PCIe bridges 532 can perform destination switching unconditionally. The PR capsule with RO=0 can act as a barrier whenever the PR capsules are pending for destinations other than the current PR capsule. It is noted that the RO behaviors are implemented in the ASI 540 as well.

The ASI 540 can implement the programmable throttle per destination-source combination. The ASI 540 can apply backpressure when the throttle limit is reached. For example, when a header throttle limit that counts the outstanding headers per destination is reached, the ASI 540 is expected to stop sending PR capsules.

The ASI 540 can match the bandwidth of the destination and deliver capsules in the order given by the ASI-PCIe bridges 532. In some embodiments, rate matching FIFO buffers can be implemented in the ASI 540 to buffer capsules to avoid under-run due to slower PCIe modes, if the same is not already done by the ASI-PCIe bridges 532. The ASI 540 can also forward the PRCs from the destination in the order of the PRs.

In some embodiments, the ASI-AXI bridge 534 as a destination for MRDMA Rx capsules does not provide a Bresponse-based PRC.

According to embodiments of the present disclosure, NPR flows can be used for PCIe memory read (PCIe MRd) messages memory reads and so on. The ASI-PCIe bridges 532 are responsible to enforce the ordering rules for NPRs according to the existing PCIe specification.

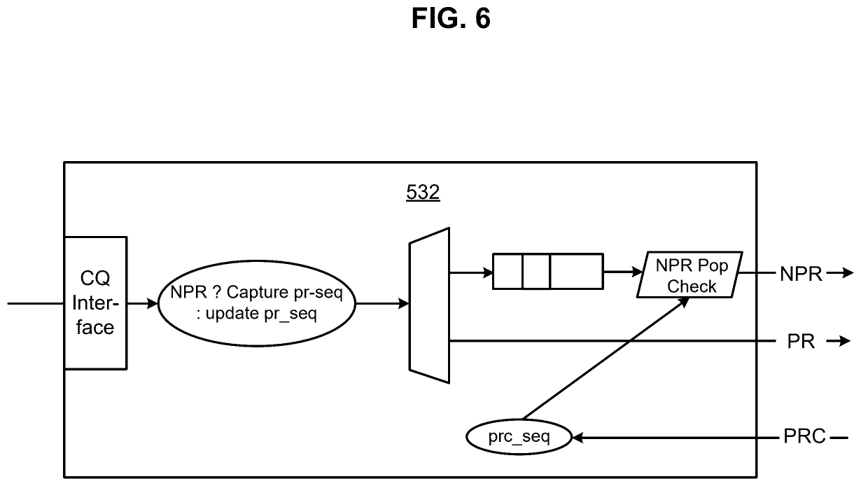

The ASI-PCIe bridges 532 can implement an ordering scheme for NPRs. FIG. 6 illustrates a schematic diagram of an NPR ordering scheme implemented at the ASI-PCIe bridges 532, in accordance with an example embodiment of the present disclosure. As illustrated in FIG. 6, a PCIe controller provides posted and non-posted TLPs in the order received from the PCIe bus on a CQ interface of the ASI-PCIe bridges 532. The ASI-PCIe bridges 532 form NPR capsules from the CQ interface. The ASI-PCIe bridges 532 capture the PR sequence numbers (pr_seq) for NPR capsules and queues the NPRs in a FIFO buffer. In some embodiments, the PRs are allowed to bypass the NPRs. The total storage for NPR capsules should be sufficient to absorb the PR->PRC worst case target latency (e.g., 255 clocks). In some embodiments, NPRs with and without payload are handled differently in the ASI-PCIe bridges 532. For example, an NPR without a payload will be popped when npr. pr_seq<=prc_seq. In some embodiments, the NPRs are allowed to be processed in any order, so that destination switching doesn't need special checks.

Referring back to FIGS. 5A and 5B, the ASI 540 can also implement an ordering scheme for NPRs. The ASI 540 delivers the NPR capsules in-order to their destination based on the destination credit. The ASI 540 maintains outstanding request and completion data per destination. The ASI 540 can throttle the source when the outstanding header and data exceeds the program threshold to avoid HOL blocking.

The ASI-AXI bridge 534 and the ASI interface 535 can also implement their ordering schemes for NPRs. The ASI-AXI bridge 534 and the ASI interface 535 can process NPRs from the source (e.g., the ASI-PCIe bridges 532) in any order for performance reasons. Each of the ASI-AXI bridge 534 and the ASI interface 535, as a destination, can absorb a guaranteed number of NPR capsules to avoid HOL blocking. The ASI interface 535 can provide a guaranteed completion buffer for NPRs to avoid deadlock and HOL blocking.

As illustrated in FIG. 5B, when the ASI-PCIe bridges 532 function as a CMPL destination, the ASI-AXI bridge 534, as a CMPL source, can form CMPL capsules, for example, using r* interface and the metadata from NPR capsules stored in the ASI-AXI bridge 534. The ASI-AXI bridge 534 can deliver the CMPL capsules in the same order as data received from the AXI4. It should be understood that the CMPL capsules are in response to the NPR capsules.

As illustrated in FIG. 5B, when the ASI-PCIe bridges 532 function as a CMPL destination, the ASI interface 535, as a CMPL source, can return CMPLs to the ASI-PCIe bridges 532 as per the PCIe definition. The ASI interface 535 can also provide the guaranteed data buffering advertised for NPR throttle to avoid HOL blocking.

As illustrated in FIG. 5B, the ASI 540 can provide a VFIFO buffer for each NPR source-VC combination, and can always deliver CMPLs in-order. The ASI-PCIe bridges 532 can process the CMPL capsules in-order and form the TLPs on the CC interface. Certain fields required for a CMPL TLP are captured from the NPR capsules and stored at the ASI-PCIe bridges 532. For example, an NPR descriptor for advanced error reporting (AER) can be captured from an NPR capsule.

The ASI-AXI bridge 534, as a source, implements the AXI4 ordering rules/requirements, where the order enforcement is done by the PS initiator (e.g., an accelerated processing unit (APU) or a network module unit (NMU)) via a NoC. For area reduction, most of the accelerator-to-controller (A2C) paths can be relocated to the ADx. The AXIB can perform the A2C address translation, and the AXI4 to ASI capsule conversion can be performed by the QDMA 536.

For DMA read ordering, host-to-controller (H2C), memory-to-memory (M2M) and descriptor engines can perform DMA reads to the ASI-PCIe bridges 532 or the ASI-AXI bridge 534 using the NPR initiator interface. All engines depend on the relaxed ordering to achieve the best performance. The DMA read requests may not have any ordering dependency with the PRs. The QDMA 536 implements the RRU 539 to reassemble the read completions. For example, the read completions from the ASI-PCIe bridges 532 may be out of order according to the existing PCIe specification. The read completions from the AXI4 may be in-order per AxID.

For DMA write ordering, controller-to-host (C2H), M2M and CMPT engines can perform DMA write to the ASI-PCIe bridges 532 or the ASI-AXI bridge 534 using the NPR initiator interface. The PR capsules are expected to be delivered in-order per wr_req_vc. The associated PRC capsules are expected to be returned in-order per wr_req_vc. The PRC capsules are returned by the destination after data is committed to the ordering domain. For the ASI-PCIe bridges 532, a PRC is returned after a PR capsule is delivered to the PCIe controller posted buffer. For the ASI-AXI bridge 534, a PRC is returned in-order per VC after the Bresponse for a given PR capsule is received. The user logic is responsible to determine whether the DMA write is committed to the ordering domain based on the PRC. The PRC is delivered to user logic using the QDMA interfaces.

The ASI interface 535 can be used to implement functionalities not supported natively via a standard AXI-MM interface or via QDMA interfaces. The ASI interface 535 can use the KS-B style ASI capsule and be presented to the application layer on a simpler AXI4 interface.

The ASI interface 535 supports the PCIe ordering rules with respect to the traffic on other interfaces. The application logic has the option to customize the ordering as per the use-case. For flow control, the PR capsules expect the guaranteed buffering for each PCIe source in the user application. The credit return is overlaid on the PRC interface. CMPL flows may have unlimited credit. The requestor is expected to guarantee space for completions.

PR and NPR flows are independent and can implement FIFO order. Upon committing the PR TLPs to the RQ interface, a PRC will be generated back to the ASI 540 to help the initiator implement ordering enforcement. The ASI initiators are responsible for order enforcement. To implement NPR pushing PR behavior, the initiator waits for a PRC before issuing an NPR to make sure the NPR with RO=0 will not go ahead of the associated PR.

The PCIe completer request interface (CQ) forwards requests from the PCIe link. The CQ interfaces may be translated to ASI capsules. For example, a CPM-EP (e.g., the CPM-EP block 220 in FIG. 2A) only supports memory, message, and ATS TLP types. All other TLP types need to be responded as an AER event.

For PCIe completer request arbitration, the completer path is expected to guarantee the NPR never pass the PR. The ASI-PCIe bridges 532 track sufficient number of outstanding NPRs to absorb latency in the EP and RP modes. Both the ordering and outstanding NPRs are taken care by crediting the outstanding NPRs and requesting sufficient NPRs be pulled from the PCIe controller. The controller is expected to honor the PCIe ordering requirements.

In some embodiments, the PCIe controller and the ASI-PCIe bridges 532 may support a single VC per flow type. Any backpressures from target can cause HOL blocking. The ASI-PCIe bridges 532 may allow up to 255 PRs and 255 NPRs outstanding before the backpressure propagates to the PCIe controller. The ASI-PCIe bridges 532 can track the necessary NPR information (e.g., RO, trusted, etc.) for each PCIe tag to be used for forming proper TLPs on the CC interface.

These are translated into ASI completion capsules, initialized with fields from the requester completion interface (RC) and the NPR context. The mapping of RC fields to the ASI completion capsule is illustrated in pseudo-code cpb_rc_cpl( ).

The PCIe completer request interface (CQ) forwards requests from the PCIe link. The bridge performs a sequence of lookups to determine where each request should be routed and what translations are required for fields such as address and function ID.

For C2H ordering in the QDMA 536, a C2H DMA translates to memory write to the PCIe host or to NVMe_PS. The C2H DMA only guarantees the writes in a given wr_req_vc to go in-order, but the ordering is not guaranteed across VC or any other interfaces. The QDMA offers following ordering mechanisms to meet the application dependent ordering. In one embodiment, the QDMA tracks the packet ID (e.g., having16-bit) seen at the C2H interface for a given wr_req_vc. The transaction on CMPT interface can request for transfer to be ordered behind specific packet ID. The packet ID must always be in the past. In this case, even though there are two different interfaces using the same wr_req_vc, the CMPTs are guaranteed to be ordered behind the C2H packets. In another embodiment, the application can request for status that associated data is committed to the associated ordering domain.

For H2C request ordering in the QDMA 536, there is no ordering guarantee between two different read request VCs. For H2C requests destined to the PCIe host, the associated NPRs ordering is dependent on the PCIe ordering rules. For H2C requests destined to the NVMe_PS, the ordering is dependent on the AxID programmed in the C2A table. Any ordering of the requests with any associated DMA writes will be application specific implementation.

For H2C data ordering in the QDMA 536, the completion data from both the PCIe host and the NVMe_PS is written into the RRU rc_id. The completion data from PCIe can be out-of-order but the RRU will reorder the data to match the ordering with the request order.

For M2M ordering in the QDMA 536, an M2M completion is delivered to the user application after the write request has been committed to the PCIe ordering domain.

For CMPT ordering in the QDMA 536, a CMPT entry is expected to be sent after the associated DMAs are complete. For C2H, the CMPT engine upon request can order behind the associated DMA write. The CMPT engine internally takes care of the ordering of CMPTQE->Status descriptor->Interrupt.

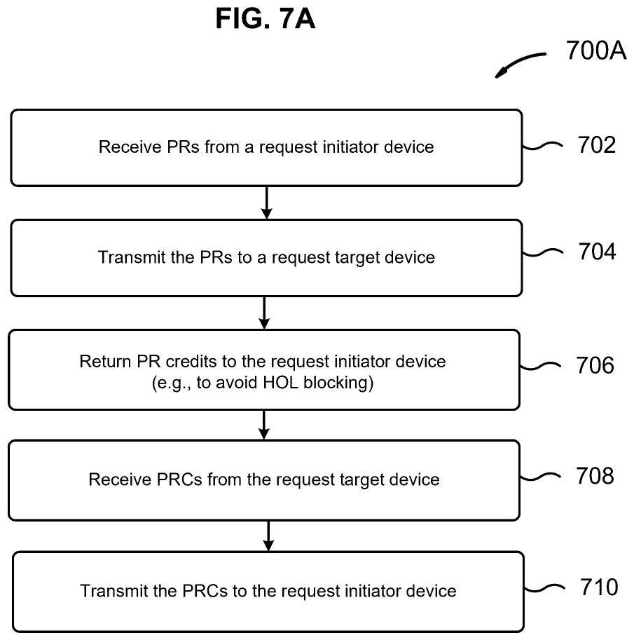

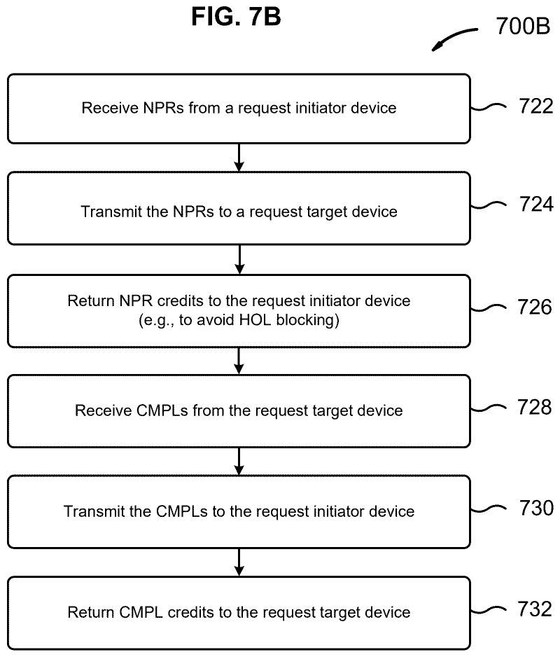

FIG. 7A illustrates a flowchart 700A of a method for managing traffic flow by an ASI, in accordance with an example embodiment of the present disclosure. The method illustrated in the flowchart 700A will be described with reference to FIG. 5A.

In block 702, the ASI receives one or more PRs from a request initiator device. In one embodiment, with reference to FIG. 5A, the QDMA 536 is a request initiator device. For example, the PR scheduler 531 of the QDMA 536 can transmit PRs to the PR VFIFO buffer 543.

In block 704, the ASI transmits the PRs to a request target device. In FIG. 5A, after the PRs from the QDMA 536 exit the PR VFIFO buffer 543, they are transmitted to the ASI-PCIe bridges 532 (e.g., the request target device).

In block 706, the ASI returns PR credits to the request initiator device. In FIG. 5A, after the PRs from the QDMA 536 exit the PR VFIFO buffer 543, the PR VFIFO buffer 543 returns credits corresponding to the number of PRs exited to the QDMA 536 (e.g., to the PR scheduler 531) per VC.

In block 708, the ASI receives one or more PRCs from the request target device. In FIG. 5A, after the PRs from the QDMA 536 are committed to the ordering domain of the ASI-PCIe bridges 532, the ASI-PCIe bridges 532 generate PRCs and transmit them back to the QDMA 536 through the ASI 540. As illustrated in FIG. 5A, the ASI 540 receives PRCs (e.g., RQ PRCs) from the ASI-PCIe bridges 532.

In block 710, the ASI transmits the PRCs to the request initiator device. As illustrated in FIG. 5A, the ASI 540 transmits the PRCs received from the ASI-PCIe bridges 532 to the PRC VFIFO buffer 533 in the QDMA 536.

In the embodiment above, the QDMA 536 (e.g., having one or more DMA engines) is the request initiator device, and the ASI-PCIe bridges 532 are the request target device. It should be appreciated that in other embodiments, the method illustrated in FIG. 7A can be performed with other request initiators and request targets. For example, any one of the ASI-PCIe bridges 532, the ASI-AXI bridge 534 (e.g., coupled to a processor subsystem), and the ASI interface 535 (e.g., having one or more user ports) can be the request initiator device, while any one of the QDMA 536 (e.g., having one or more DMA engines), the ASI-AXI bridge 534 (e.g., coupled to a processor subsystem), and the ASI interface 535 (e.g., having one or more user ports) can be the request target device, as described above with reference to FIG. 5A.

FIG. 7B illustrates a flowchart 700B of another method for managing traffic flow by an ASI, in accordance with an example embodiment of the present disclosure. The method illustrated in the flowchart 700B will be described with reference to FIG. 5B.

In block 722, the ASI receives one or more NPRs from a request initiator device. In one embodiment, with reference to FIG. 5B, the QDMA 536 is a request initiator device. For example, the NPR scheduler 537 of the QDMA 536 can transmit NPRs to the NPR VFIFO buffer 545.

In block 724, the ASI transmits the NPRs to a request target device. In FIG. 5B, after the NPRs from the QDMA 536 exit the NPR VFIFO buffer 545, they are transmitted to the ASI-PCIe bridges 532 (e.g., the request target device).

In block 726, the ASI returns NPR credits to the request initiator device. In FIG. 5B, after the NPRs from the QDMA 536 exit the NPR VFIFO buffer 545, the NPR VFIFO buffer 545 returns credits corresponding to the number of NPRs exited back to the QDMA 536 (e.g., to the NPR scheduler 537) per VC.

In block 728, the ASI receives one or more CMPLs from the request target device. In FIG. 5B, after the ASI-PCIe bridges 532 complete processing of the NPRs received from the ASI 540 (e.g., read data is ready to be sent back to the request initiator device), the ASI-PCIe bridges 532 generate CMPLs and transmit them back to the QDMA 536 through the ASI 540. As illustrated in FIG. 5B, the ASI 540 receives CMPLs (e.g., RC CMPLs) from the ASI-PCIe bridges 532.

In block 730, the ASI transmits the CMPLs to the request initiator device. In FIG. 5B, the ASI 540 transmits the CMPLs received from the ASI-PCIe bridges 532 to the RRU 539 in the QDMA 536.

It should be noted that in the embodiment above, the QDMA 536 (e.g., having one or more DMA engines) is the request initiator device, and the ASI-PCIe bridges 532 are the request target device. It should be appreciated that in other embodiments, the method illustrated in FIG. 7B can be performed with other request initiators and request targets. For example, any one of the ASI-PCIe bridges 532, the ASI-AXI bridge 534 (e.g., coupled to a processor subsystem), and the ASI interface 535 (e.g., having one or more user ports) can be the request initiator device, while any one of the QDMA 536 (e.g., having one or more DMA engines), the ASI-AXI bridge 534 (e.g., coupled to a processor subsystem), and the ASI interface 535 (e.g., having one or more user ports) can be the request target device, as described above with reference to FIG. 5B.

In block 732, the ASI may optionally return CMPL credits to the request target device. In FIG. 5B, after the CMPL VFIFO buffer 547 can return credits corresponding to the number of CMPLs exited back to one or more request targets (e.g., the ASI-AXI bridge 534 and/or the ASI interface 535).

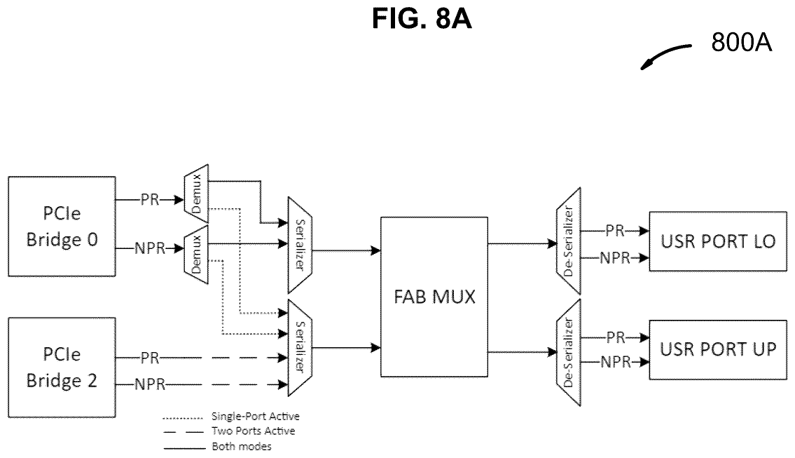

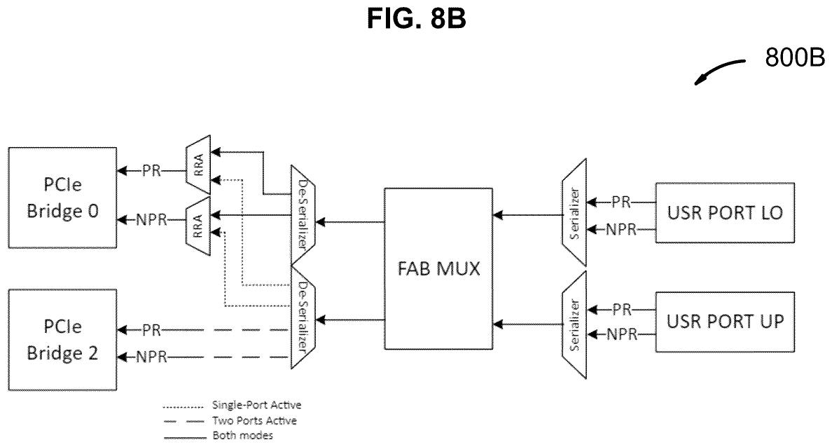

FIG. 8A illustrates a schematic routing diagram 800A for transmitting PRs and NPRs from PCIe bridges to user ports, in accordance with an example embodiment of the present disclosure. FIG. 8B illustrates a schematic routing diagram 800B for transmitting PRs and NPRs from user ports to PCIe bridges, in accordance with an example embodiment of the present disclosure.

In the embodiments shown in FIGS. 8A and 8B, two PCIe bridges and two user ports are supported. In some embodiments, only one PCIe bridge may be supported. For example, if only one PCIe bridge is supported (e.g., in a 1-port mode), PCIe Bridge 0 can send and receive capsules from both User Port-LO and User Port-UP. In another example, if two PCIe bridges are supported (e.g., in a 2-port mode), PCIe Bridge 0 can only send/receive capsules from User Port-LO, and PCIe Bridge 2 can only send/receive CSI capsules from User Port-UP.

In FIG. 8A, although the serializer towards User Port-UP shows inputs from both PCIe Bridges, those two pathways are mutually exclusive, and are not expected to be active at the same time. Similarly, FIG. 8B shows PR and NPR routing in the opposite direction. In the embodiments shown in FIGS. 8A and 8B, both User Port-LO and User Port-UP are always active and available for usage, but depending on the PCIe Port mode, the connectivity between PCIe bridges and user ports can vary.

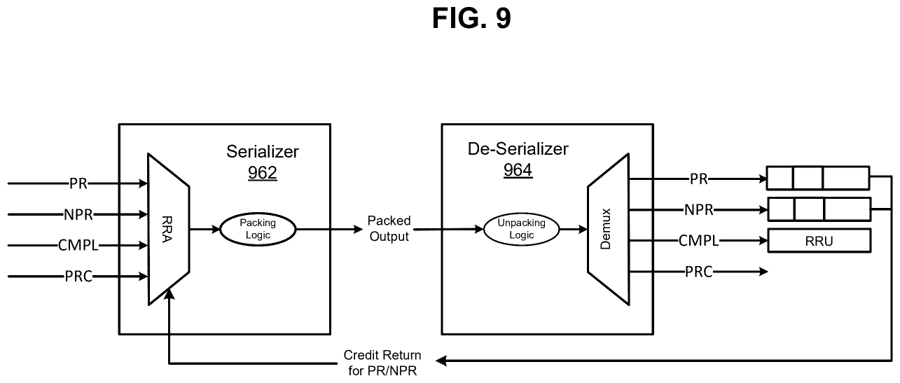

FIG. 9 illustrates a schematic diagram showing a sample usage for a serializer and a de-serializer, in accordance with an example embodiment of the present disclosure. As illustrated in FIG. 9, in order to convert between packed and unpacked interfaces, an ASI can use a serializer module 962 and de-serializer module 964 that can arbitrate between multiple unpacked interfaces to a single packed interface. The arbitration can occur on the capsule boundary with no interleaving between flow types. In some embodiments, the serializer module 962 can have input interfaces tied off to provide a single unpacked-to-packed interface conversion as well. In some embodiments, the serializer/de-serializer combination can be used for all packed interfaces (e.g., NPR, User Port) for reducing pins for lower-bandwidth interfaces.

As illustrated in FIG. 9, a crediting logic can be used by the user port packed interfaces. In the user port use-case, the PL has a FIFO per flow type and per VC (e.g., up to 2 per capsule type depending on number of active PCIe controllers). In some embodiments, FIG. 9 illustrates the flow of NR or NPR credit return from an ASI to a user port.

In FIG. 9, by using the serializer and de-serializer combination, the ASI interface (e.g., the user port(s)) can have shared pins at low cost resulting in a narrow interface (e.g., having a reduced width), which can expose TLPs to the programmable logic while maintaining the PCI ordering rules. In addition, the cost of the programming logic is minimal because the bulk of data traverses through the other paths (e.g., the QDMA paths). Hence, little customization is needed over this narrow interface, as the ASI interface can maintain the ordering rules as per the PCIe specification or as per the AXI interface specification.

According the embodiments of the present disclosure, the ASI can offer data path protection. For example, the ASI can provide a 32-bit CRC field for usage with PR and CMPL capsules. The CRC field may cover data protection for the data, but does not include any of the header bits. The CRC is pipelined through the ASI and sent to the destination alongside the capsule. The request target can perform CRC checking using a payload check bit in the capsule header. For packed interfaces, the CRC is appended as the last 4 dwords of packed data. The ASI is responsible for extracting the CRC and passing it along to the destination interfaces, but without maintaining any internal CRC checks. In some embodiments, random access memory (RAM) error correcting code (ECC) can be implemented for data protection while stored in the VFIFO RAMs. If double-bit ECC errors are detected in the RAMs in the ASI while capsules are being processed, then all capsules from that point on will be labelled with a data integrity error status. This error will also be logged accordingly, and the error containment feature can be toggled via CSR.

According the embodiments of the present disclosure, the ASI can reduce the overall area cost while reducing latency and without sacrificing bandwidth. The ASI allows multiple adaptable requesters, such as bulk data DMA engines and queue engines with customizable APIs (WQE formats and/or modes of operation), to be in the PL while leveraging hardened bulk data movers to optimize PL usage. The PL can provide flexible solutions to handle applications or functions that the hardened devices cannot handle.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A system-on-chip (SoC), comprising:
a request initiator device;
a request target device;
an adaptable streaming interconnect (ASI) communicatively coupled to the request initiator device and the request target device;
wherein the ASI is configured to:
receive a posted request (PR) from the request initiator device;
transmit the PR to the request target device;
receive a posted request complete (PRC) from the request target device; and
transmit the PRC to the request initiator device.

2. The SoC of claim 1, wherein the request initiator device is configured to enforce an ordering requirement of the PR based on the PRC.

3. The SoC of claim 1, wherein the PRC is generated by the request target device in response to data in the PR being committed to an ordering domain of the request target device.

4. The SoC of claim 1, wherein the ASI is further configured to:
return a PR credit to the request initiator device when the PR exits a PR buffer of the ASI to avoid head-of-line (HOL) blocking.

5. The SoC of claim 1, wherein the request initiator device comprises one of:
a Peripheral Component Interconnect express (PCIe) bridge;
a direct memory access (DMA) engine;
a processor subsystem; and
a user port.

6. The SoC of claim 1, wherein the request target device comprises one of:
a Peripheral Component Interconnect express (PCIe) bridge;
a direct memory access (DMA) engine;
a processor subsystem; and
a user port.

7. The SoC of claim 1, wherein the ASI is further configured to:
receive a non-posted request (NPR) from the request initiator device;
transmit the NPR to the request target device;
receive a non-posted request completion (CMPL) associated with the NPR from the request target device; and
transmit the CMPL to the request initiator device.

8. The SoC of claim 7, wherein the ASI is further configured to:
return an NPR credit to the request initiator device when the NPR exits an NPR buffer of the ASI to avoid head-of-line (HOL) blocking.

9. The SoC of claim 7, wherein the ASI is further configured to return a CMPL credit to the request target device when the CMPL exits a CMPL buffer of the ASI.

10. A method by an adaptable streaming interconnect (ASI), the method comprising:
receiving a posted request (PR) from a request initiator device;
transmitting the PR to a request target device;
receiving a posted request complete (PRC) from the request target device; and
transmitting the PRC to the request initiator device.

11. The method of claim 10, wherein the PRC is used by the request initiator device to enforce an ordering requirement of the PR.

12. The method of claim 10, wherein the PRC is generated by the request target device in response to data in the PR being committed to an ordering domain of the request target device.

13. The method of claim 10, further comprising:
returning a PR credit to the request initiator device when the PR exits a PR buffer of the ASI to avoid head-of-line (HOL) blocking.

14. The method of claim 10, wherein the request initiator device comprises one of:
a Peripheral Component Interconnect express (PCIe) bridge;
a direct memory access (DMA) engine;
a processor subsystem; and
a user port.

15. The method of claim 10, wherein the request target device comprises one of:
a Peripheral Component Interconnect express (PCIe) bridge;
a direct memory access (DMA) engine;
a processor subsystem; and
a user port.

16. The method of claim 10, further comprising:
receiving a non-posted request (NPR) from the request initiator device;
transmitting the NPR to the request target device;
receiving a non-posted request completion (CMPL) associated with the NPR from the request target device; and
transmitting the CMPL to the request initiator device.

17. The method of claim 16, further comprising:
returning an NPR credit to the request initiator device when the NPR exits an NPR buffer of the ASI to avoid head-of-line (HOL) blocking.

18. The method of claim 16, further comprising:
returning a CMPL credit to the request target device when the CMPL exits a CMPL buffer of the ASI.

19. An adaptable streaming interconnect (ASI) communicatively coupled to a request initiator device and a request target device, the ASI comprising:
circuitry configured to:
receive a posted request (PR) from the request initiator device;
transmit the PR to the request target device;
receive a posted request complete (PRC) from the request target device; and
transmit the PRC to the request initiator device.

20. The ASI of claim 19, wherein the circuitry is further configured to return a PR credit to the request initiator device when the PR exits a PR buffer of the ASI to avoid head-of-line (HOL) blocking.
